(19) United States
(12) Patent Application Publication
(10) Pub. No.: US 2021/0374451 A1
(43) Pub. Date: Dec. 2, 2021

(54) COMPRESSION FOR PERSONALIZED HANDWRITING SYSTEM

(71) Applicant: Michael Margolis, (US)

(72) Inventor: Michael Margolis, Las Cruces, NM (US)

(73) Assignee: Michael Margolis, Las Cruces, NM (US)

(21) Appl. No.: 17/303,539

(22) Filed: Jun. 1, 2021

Related U.S. Application Data
(60) Provisional application No. 63/032,250, filed on May 29, 2020.

(51) Int. Cl. G06K 9/22; H03M 7/40; G06K 9/00; G06F 3/0488

(52) U.S. Cl. CPC G06K 9/222; G06F 3/04883; G06K 9/00416; H03M 7/40

(57) ABSTRACT

In embodiments of the invention, a compression system for a mobile messaging application is disclosed in which messages are received over a communication link in what appears to be the sending user's personal handwriting.

### PRIORITY CLAIM

This application claims priority to U.S. Patent Application No. 63/032,250, filed May 29, 2020, titled, “COMPRESSION FOR PERSONALIZED HANDWRITING SYSTEM,” the contents of which is incorporated by reference in its entirety.

### BACKGROUND

In embodiments of the invention, a compression system for a mobile messaging application is disclosed in which messages are received over a communication link in what appears to be the sending user's personal handwriting.

### BRIEF DESCRIPTION OF THE DRAWINGS

The features and advantages of the present disclosure will be more fully understood with reference to the following detailed description when taken in conjunction with the accompanying figures, wherein:

FIG. 1 illustrates an exemplary pixel array for storing a representation of a user's handwriting, according to one embodiment of the present disclosure.

FIG. 2 illustrates an exemplary bitmap array, according to one embodiment of the present disclosure.

FIG. 3 illustrates an exemplary array containing runs of ones and zeroes read from a bitmap array, according to one embodiment of the present disclosure.

FIG. 4 illustrates a consolidated single string representative of the array shown in FIG. 3, according to one embodiment of the present disclosure.

FIG. 5 illustrates a compressed strong representative of an original bitmap array, according to one embodiment of the present disclosure.

FIG. 6 illustrates a bitmap array following a compression system according to one embodiment of the present disclosure.

FIG. 7 illustrates the bitmap array of FIG. 6 following runlength processing according to one embodiment of the present disclosure.

FIG. 8 illustrates the data of FIG. 8 following concatenation into a single string, according to one embodiment of the present disclosure.

FIG. 9 illustrates an exemplary system for implementing the compression system according to one embodiment of the present disclosure.

FIG. 10 illustrates a sample mobile app implementing a handwriting compression according to one embodiment of the present disclosure.

### DETAILED DESCRIPTION

In embodiments of the invention, a compression scheme for use with a mobile application is disclosed, enabling a user to, for example, send an electronic message—whether by SMS, iMessage, e-mail or otherwise—that appears on the receiving end in the user's personal handwriting rather than ASCII text. These messages may be referred to as electronic handwritten messages.

In embodiments of the invention, the user is enabled to easily set up a personalized font in the user's own handwriting so that recipients of the messages containing the custom font would see the message in the user's handwriting, adding a personalized element to the exchange. In embodiments of the invention, the user may enter the message on their mobile computing device as normal. A compression system is provided for reducing the quantity of data transmitted over the communication channel, which system is especially well-suited for use with handwriting data.

### A Compression System for Data

A system for receiving, compressing, storing, and transmitting a user's handwriting over a messaging link will now be described.

In a preferred embodiment, a mobile computing device having a touchscreen receives data corresponding to the user's handwriting that has been entered on the touchscreen in a bitmap format, an uncompressed image format in which each pixel in the image is represented by single bit or group of bits.

Alternative file formats may be used in the initial capture (e.g., PNG, JPEG, TIFF) and converted to a bitmap format for compression. These file formats are less suitable for compressing the data corresponding to handwriting, and a conversion to a bitmap format before employing the compression system of the present invention will enhance the results.

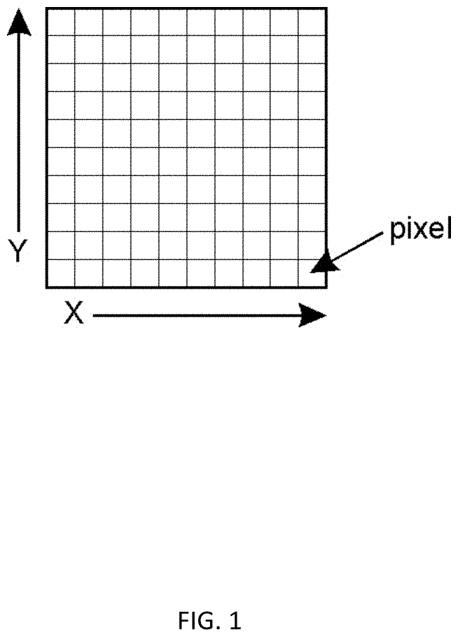

In embodiments of the invention, the image of the user's handwriting may be stored in a rectangular pixel array wherein the pixels appear left-to-right along an X-axis and top-to-bottom along a Y-axis. In a preferred embodiment, the pixel array initially comprises four bytes and has four channels, including a red, green, blue, and alpha channel. An exemplary pixel array is displayed in FIG. 1.

In embodiments of the invention, an array may contain pixel data indicated multiple color channels (e.g., red, green, and blue), and an alpha channel that represents the transparency of the pixel. In embodiments, an alpha channel value may range from a value of 100% indicating full opacity to 0% indicating full transparency. In embodiments, the color channels for the image may be disregarded because the handwriting sample is monochromatic. The system may then proceed by processing only the alpha channel.

In embodiments of the invention, the pixels date in the array are read beginning where the x value will start from zero (i.e., 0, 0) then increment while alpha values for every y will be zero. Once there is an alpha value greater than zero the x value will be recorded as x minimum. The next loop will start from x-maximum and will do the same but will decrement until reaching the x-maximum. To reach a multiple of four, the minimum will decrement or maximum will increment until a multiple of four is reached.

The pixel array data file with white spaces removed is then further processed. Since each letter in the sample will typically have a uniform color, the only important data point is an alpha file.

Any alpha greater than 0 is assigned TRUE and any alpha 0 is assigned FALSE to create a Boolean array of alpha-only values.

The Boolean array may then be compressed to form an alpha bit file in which each bit represents a pixel alpha value. This representation of bits representing pixels in which 1 is TRUE and 0 is FALSE is referred to as an alphabit file. Since there is only one bit representing a pixel and 8 pixels can be compressed in 1 byte instead of 4 bytes per pixel, significant compression can be obtained.

The data in the alphabit file is then further compressed, as described below.

It has been found that the dataset comprising personal handwriting data is particularly well-suited for the compression system of the present invention because the dataset exhibits a high incidence of repeated integers.

The first bit of the compressed array is then read. For example if the very first bit is a 1 the very first bit in the compressed array will be a 1 and if the first bit is a 0 very first bit of compressed array will be 0.

The next sequence will be is and the amount of is will consist of the number of bits in the repeated sequence. For example, if there is a sequence of 8 repeats, 8 is a 4-bit number which would be 1000. So there will be a sequence after the first bit of 4 1s. Following is a 0 which represents a break. The next sequence will be the number of repeats with the bits after the last bit. Since the fourth bit is already assumed to be 1 there are only 3 subsequent bits that are read. So the 8 repeats is then 000 to represent 8. The next sequence will repeat the whole cycle if the next bit is a 1. If the next bit is a 0, the compression will stop.

At the end of the compression file trailing zeroes are added to make sure the number of bits of compression file is a multiple of 8.

For example, assume a file represented by 00000111001111111. (It will be appreciated that this abbreviated file is for example only to illustrate the operation of the compression a system of the present invention.)

In this example, the first bit is 0 so the first bit of compressed dataset will be 0. There are a total of 5 0s in the first run, and since 5 is a three-bit number (i.e., 101), the next sequence will be 3 1s. A 0 is added. A value of 5 in binary is 101. Since it is already known that the third bit is 1 we only need the first 2 bits which is 01. So, a starting sequence will be 0111001. The subsequent sequence is 3 ones and since 3 is a two-bit number, two ones and a zero are added to the compressed data. The cycle repeats for all the data in the uncompressed set.

The compressed file conversion of 00000111001111111 is represented by 011100111011100111011000.

Significant compression is obtained in actual data where there are a significant number of repeated numbers.

### Example 1

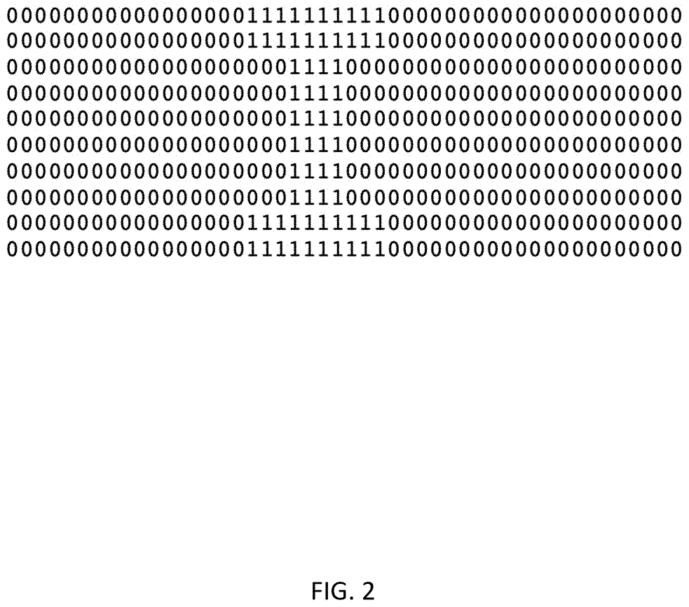

In a first example, the compression system of the present invention is applied to a 48×10-pixel bitmap, represented in FIG. 2.

The bitmap has a total of 480 pixels, each represented by a single bit for a total of 480 bits or 60 bytes.

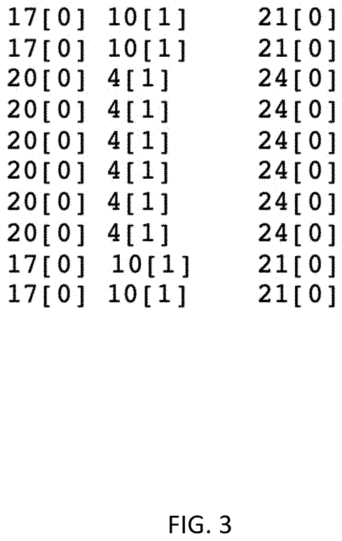

As shown in FIG. 3, the first line of the bitmap data beings with a run of 17 zeroes followed by a run of 10 ones, followed by a run of 21 zeroes. Counting the zeroes and ones in the bitmap, line by line, results in what is shown in FIG. 3.

It will be appreciated by those having ordinary skill in the art that the foregoing array need not be generated as part of the compression system of the present invention and may be implanted in alternative data structures.

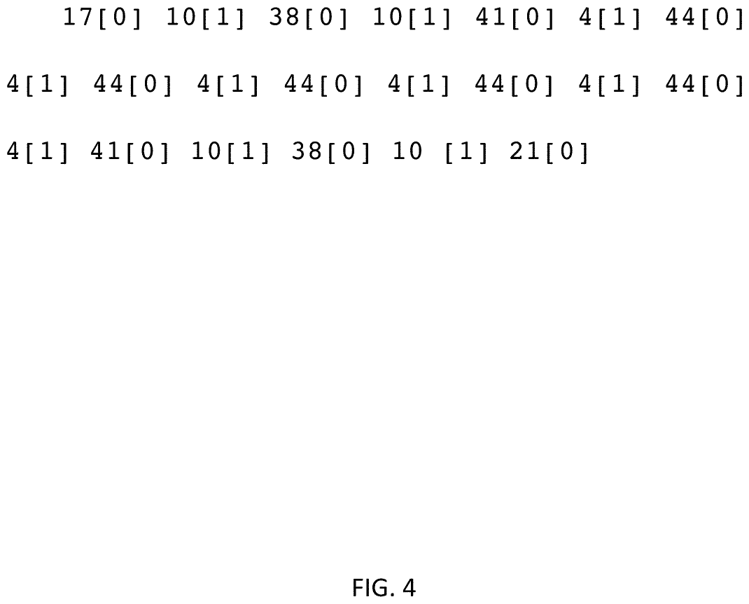

Consolidating the rows of the bitmap into a single string results in the data shown in FIG. 4.

Runs of a single digit extending from one line to the next have thus been concatenated, removing further redundancy by extending the length of individual runs and removing the total number of runlength units to compress. For example, as shown in FIG. 4, the run of 21 zeroes at the end of the line has been concatenated with the 17 zeros at the beginning of the second line for a total of 38 consecutive zeroes.

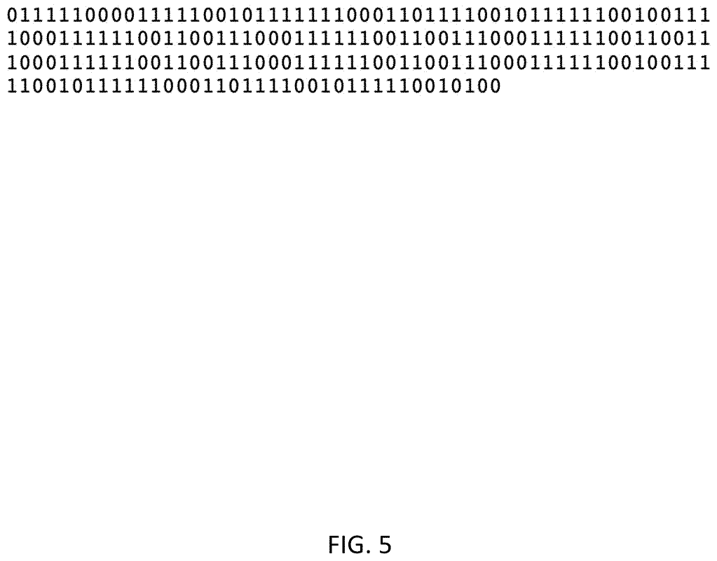

Referring to FIG. 5, a compressed string is shown representing the original bitmap data in FIG. 2 after compression by the system of the present invention.

The original 60-byte bitmap has been compressed to 25 bytes for a reduction of 58.34%.

### Example 2

In a second example, the compression system of the present invention is applied to a 20×10-pixel bitmap representing a letter 1′.

The bitmap has a total of 200 pixels, each represented by a single bit for a total of 25 bytes.

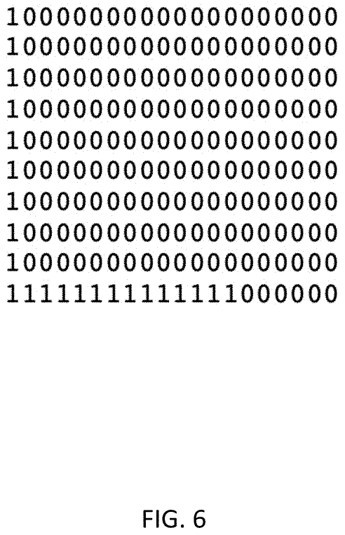

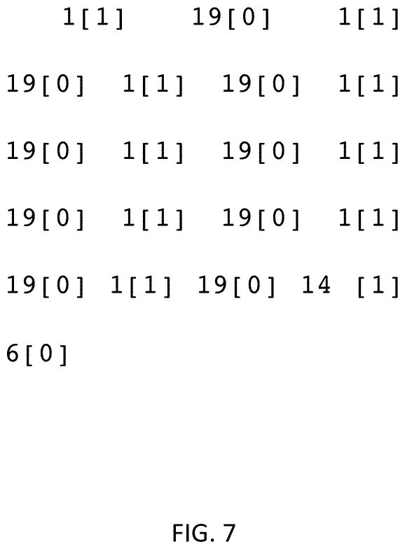

As shown in FIG. 6, the first line of the bitmap data beings with a run of—zeroes followed by a run of—ones, followed by a run of—zeroes. Counting the zeroes and ones in the bitmap, row by row, and consolidating the runs that cross rows results in the string shown in FIG. 7.

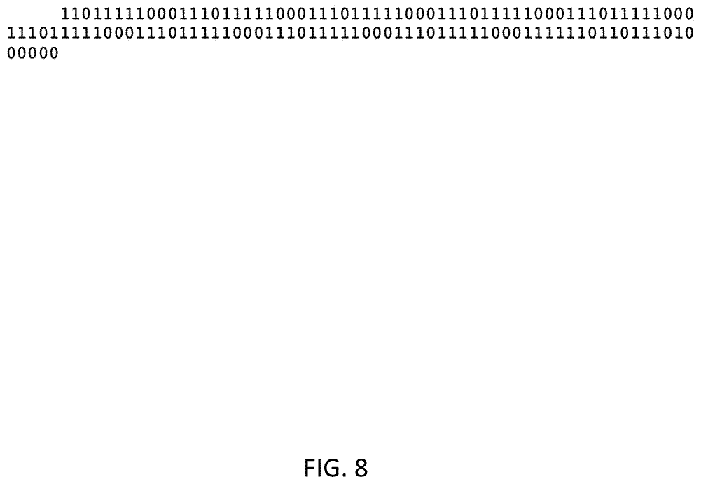

Referring to FIG. 8, a compressed string is shown representing the original bitmap data in FIG. 2 after compression by the system of the present invention.

The 128 bits in the compressed string are stored in 16 bytes, a reduction of 9 bytes, or 36%.

### An Exemplary Sample Handwriting Messaging Application

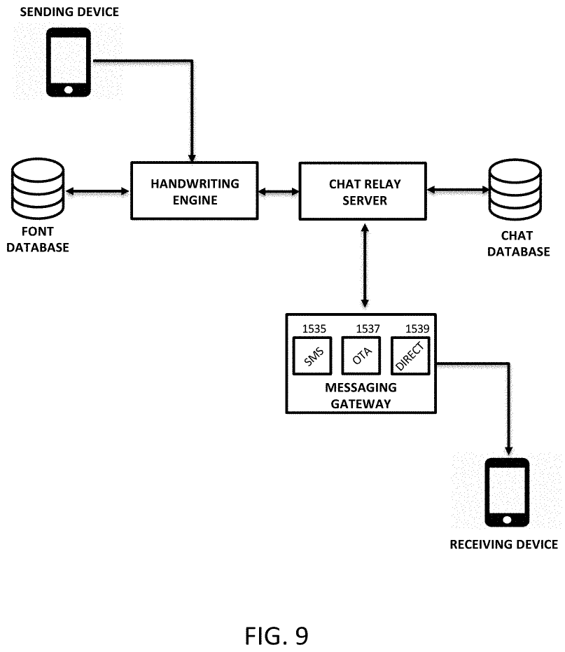

In embodiments, a system is disclosed for implementing the compression scheme described herein. FIG. 9 shows an overview of the components of an exemplary system for implementing the compression system described herein.

In embodiments, at least one mobile computing device is connected to a network such as the Internet. A messaging system may be configured to interoperate with a mobile computing device, which may be referred to as the sending device. Sending device may include any smartphone or tablet unit that is configured to communicate over a network data connection such as the Internet or a cellular telephony network. In embodiments, sending device may incorporate a processor, memory, display, battery, communications gateway, and an input device such as a keyboard or touchscreen overlay. In embodiments, sending device may be a desktop computer, laptop computer, tablet computing device, or the like.

In embodiments of the invention, sending device may be configured to run software comprising a messaging application—including a handwriting messaging application. Messaging application may take the form of software that may cause the device to perform the features discussed herein, including: (a) sending and receiving messages, including electronic handwritten messages; and (b) receiving user handwriting samples to generate fonts for use with the system, among other functions.

The device may be configured to receive and transmit messaging data and associated metadata to and from a handwriting engine over a communication gateway. In embodiments, handwriting engine, may communicate with sending device over the network connection and be generally responsible for functions related to managing user handwriting samples, coordinating setup and initiating new handwriting samples, converting ASCII text-based messages to electronic handwritten messages, and relaying those messages to the chat relay server for storage and transmission.

Handwriting engine may be coupled to or in communication with a font database, a store of user handwriting samples that may take the form of fonts or images that may be used by the handwriting engine to generate electronic handwritten messages. Software running on the sending device or handwriting engine may perform one more lookups in the font database. The handwriting engine may be subdivided into logical or physical components corresponding to system functions. Handwriting engine may be further configured to perform various operations on data stored in the fonts database.

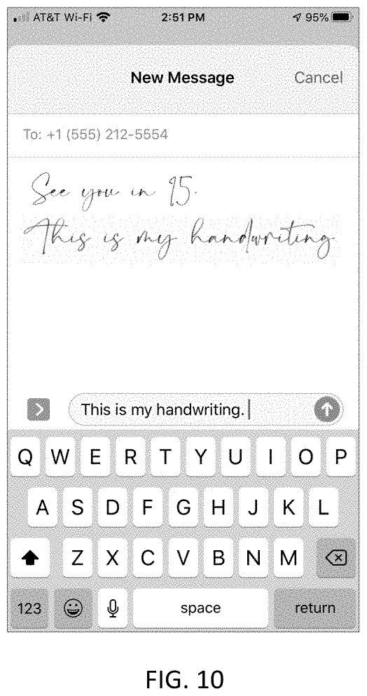

In embodiments, handwriting engine may cause software running on the sending device to display the text message in the handwritten font in real time or near real time. An example is shown in FIG. 10.

The handwriting ending may be in further communication with a chat relay server, which may take the form of a further server computing device that manages the transmission, movement, and storage of user messages, including electronic handwritten messages. A chat database may store individual user messages with metadata that includes, date, time, sender, recipient, and the like.

A messaging gateway may be in communication with the chat relay server and the receiving device. Messaging gateway may coordinate the movement of user messages from the messaging system over a network to the receiving device. Transmission may be accomplished via a conventional SMS/MMS protocol that routes the electronic handwritten message data using existing systems. In embodiments, the messaging system may utilize an over-the-top (“OTT”) platform that sends message data via an internet connection to the receiving device. Examples of OTT systems include WhatsApp, Signal, Messages (iOS), Messages (Android), Facebook Messenger, and Skype, among others. In embodiments of the invention, a proprietary custom application may be provided for use on the sending and receiving devices for interfacing with the above system components and performing the functions described herein.

A receiving device may be configured to receive electronic handwritten message data from the messaging gateway and display the same on the screen of the device. Software running on the receiving device, or running remotely, may cause the display to graphically display the handwritten electronic message.

On sending an electronic handwritten message back to the sending device, the sending and receiving devices will exchange roles, with the sender becoming the receive and vice-versa.

It will be apparent to those of ordinary skill in the art that the components described herein as discrete components may be implemented as part of a single device or single logical device. The sending and receiving devices may be considered to be independent of the messaging system described here, or a part of that system.

In embodiments of the invention, software running on the mobile computing device, or run remotely, may enable the user to set up their own personal handwriting font through a series of prompts that associate the handwriting with ASCII text, which is stored as user handwriting data. The user handwriting data may be stored in the fonts database for later recall. As described above, the user handwriting data may be in the form of graphical files—JPEG, PNG, GIF, TIFF, and the like—for each character or even common phrases.

In operation, a sending device interacting with the system may initiate a text message by entering text as the user would for any conventional messaging application.

Software running on the sending device, or remotely, may cause the ASCII text to be sent the handwriting engine, where the user handwriting data is accessed in the fonts database and a handwritten electronic message is generated. In embodiments, the handwritten electronic message may take the form of image data that has been compressed by the handwriting engine using the system described herein.

In embodiments, the handwritten electronic message may be relayed to the chat database where metadata associated with the message is recorded in the chats database. Chat server may be further configured to perform various functions on the data stored in the chats database.

A sending device or a receiving device may be a smartphone, tablet, iPod, laptop, desktop, smart TV, etc. which may include an app, internet access, or another programming to allow access to an Internet-based or cloud network. The messaging software may include allowing a sender and recipient and seller the ability to communicate.

The messaging system may be connected via communication link to various external resources. In one exemplary embodiment, the sending device executes a client software application or accesses the software via a communication gateway. The sending device may employ a mobile or local device, such as a wireless-enabled notebook computer or network-connected desktop computer or another suitable machine to connect to the central messaging system via a communication link such as the Internet, Ethernet, WLAN, WAN or another suitable network. Sending device provides, for example, a web-based, GUI-driven user interface for presenting messaging options as selected by a proprietary algorithm running on an algorithm server. Alternatively, the messaging system may be a web-based system to which a company or firm has a license and to which its employees may connect for content delivery and other services. Communication links throughout the messaging system may be a combination of wireless, LAN, WLAN, ISDN, DSL, and wireless type networks, for example. The system may comprise a typical combination of hardware and software including system memory, operating system, application programs, graphical user interface (GUI), processor, and storage which may contain electronic information. The operating system shall be suitable for use with the messaging functionality described herein, for example. Also, the messaging system client software may be browser-based and/or may include custom integration with other applications. The software and related data used to implement the messaging system client processes may be accessed via the Internet.

The system may comprise a central server and database, user interface peripherals such as drives (not shown), monitor, keyboard, and printer, and one or more additional messaging system support systems. The servers and databases may be used to communicate remotely, or locally for that matter, directly with sending device and may load, pass, receive information and instructions, such as software executable on the machine and data for storing and using locally by the sending device. All or part of the necessary connections between systems may be Internet or web-based, Ethernet, wireless network, optical network, or a combination and may be comprised of desktop-based, central server-based, or web-enabled or a combination. The computer systems used in implementing the various embodiment of the present invention may include specially-programmed, special-purpose hardware, for example, an application-specific integrated circuit (ASIC). Aspects of the invention may be implemented in software, hardware or firmware, or any combination thereof. Further, such methods, acts, systems, system elements, and components thereof may be implemented as part of the computer system described above or as an independent component.

Although the system is shown by way of example as one type of computer system upon which various aspects of the invention may be practiced, it should be appreciated that aspects of the invention are not limited to being implemented on the systems shown herein. Various aspects of the invention may be practiced on one or more computers having a different architecture or components than those shown herein. The system may be a general-purpose computer system that is programmable using a high-level computer programming language. The system may be also implemented using specially programmed, special-purpose hardware.

The processor and operating system together define a computer platform for which application programs in high-level programming languages are written. It should be understood that the invention is not limited to a particular computer system platform, processor, operating system, or network. Also, it should be apparent to those skilled in the art that the present invention is not limited to a specific programming language or computer system. Further, it should be appreciated that other appropriate programming languages and other appropriate computer systems could also be used.

One or more portions of the system may be distributed across one or more computer systems coupled to a communications network. These computer systems also may be general-purpose computer systems. For example, various aspects of the invention may be distributed among one or more computer systems configured to provide a service (e.g., servers) to one or more client computers, or to perform an overall task as part of a distributed system. For example, various aspects of the invention may be performed on a client-server or multi-tier system that includes components distributed among one or more server systems that perform various functions according to various embodiments of the invention.

It should be appreciated that the invention is not limited to executing on any particular system or group of systems. Also, it should be appreciated that the invention is not limited to any particular distributed architecture, network, or communication protocol. Various embodiments of the present invention may be programmed using an object-oriented programming language or functional, scripting, and/or logical programming languages may be used. Various aspects of the invention may be implemented in a non-programmed environment (e.g., documents created in HTML, XML or another format that, when viewed in a window of a browser program, render aspects of a graphical user interface (GUI) or perform other functions).

Various aspects of the invention may be implemented as programmed or non-programmed elements, or any combination thereof. Aspects of the invention may be embodied in software operating on a general purpose computer or special purpose hardware, a special purpose hardware machine, or business methods, and instructions fixed in a machine-readable medium. The invention may also be embodied in a method of operating a computer, a computer network, or other systems as described above. Parts of the method may be performed by a customer and other parts by a service provider. Any suitable partitioning of the system or method may be used.

The present invention can be realized in hardware, software, or a combination of hardware and software. Any kind of computing system, or other apparatus adapted for carrying out the methods described herein, is suited to perform the functions described herein. A typical combination of hardware and software could be a specialized or general purpose computer system having one or more processing elements and a computer program stored on a storage medium that, when loaded and executed, controls the computer system such that it carries out the methods described herein. The present invention can also be embedded in a computer program product, which comprises all the features enabling the implementation of the methods described herein, and which, when loaded in a computing system can carry out these methods. Storage medium refers to any volatile or non-volatile storage device.

It will be appreciated by persons skilled in the art that the present invention is not limited to what has been particularly shown and described hereinabove. In addition, unless mention was made above to the contrary, it should be noted that all of the accompanying drawings are not to scale. A variety of modifications and variations are possible in light of the above teachings without departing from the scope and spirit of the invention.

We claim:

1. A computer-implemented method for sending and receiving handwritten electronic messages, comprising:
receiving a digital handwritten message on a touchscreen input device operably connected to a processor, a memory, a display, and a communication gateway;
receiving, on the touchscreen input device, a digital handwritten message and using the processor to convert the digital handwritten message to uncompressed bitmap data;
employing the processor to load the uncompressed bitmap data into a pixel array configured to represent data indicative of at least one color channel and an alpha channel and storing the pixel array in the memory;
employing the processor to process the alpha channel data by reading the pixel array from the memory and discarding any whitespace to generate an alphabit array wherein any alpha greater than zero is assigned TRUE and any alpha of zero is assigned FALSE, and storing the alphabit array in the memory;
employing the processor to apply a compression scheme to the alphabit array by loading the same from the memory and generating compressed alphabit array in which: (i) the first bit of the compressed alphabit array is assigned the value of the first bit on the alphabit file; (ii) a coding algorithm is used to convert runs of ones and zeroes in the alphabit array to codes representative of the equivalent runlength of those runs of ones and zeroes, until all data in the alphabit file has been converted; and (iii) padding the compressed alphabit array with as sufficient number of trailing zeros to make the number of bits in the compressed alphabit array a multiple of eight; and
employing the processor and communication interface to transmit the compressed alphabit array to a remote computing device.

2. A system for sending and receiving handwritten electronic messages, comprising:
a processor, a memory, a display, a communication gateway, and a touchscreen input device, wherein the processor is operative to:
(a) receive a digital handwritten message on the touchscreen input device, convert the digital handwritten message to uncompressed bitmap data;
(b) load the uncompressed bitmap data into a pixel array configured to represent data indicative of at least one color channel and an alpha channel;
(c) process the alpha channel data in the pixel array by discarding any whitespace to generate an alphabit array wherein any alpha greater than zero is assigned TRUE and any alpha of zero is assigned FALSE;
(d) apply a compression scheme to the alphabit array to generate a compressed alphabit array in which: (i) the first bit of the compressed alphabit array is assigned the value of the first bit on the alphabit file; (ii) a coding algorithm is used to convert runs of ones and zeroes in the alphabit array to codes representative of the equivalent runlength of those runs of ones and zeroes, until all data in the alphabit file has been converted; and (iii) padding the compressed alphabit array with as sufficient number of trailing zeros to make the number of bits in the compressed alphabit array a multiple of eight; and
(e) transmitting, over the communication interface, the sending the compressed alphabit array over the communication interface to a remote computing device.
